(19) United States
(12) Patent Application Publication
(10) Pub. No.: US 2026/0088729 A1
(43) Pub. Date: Mar. 26, 2026

(54) CURRENT CONVERTER, ELECTRIC DRIVE DEVICE AND METHOD FOR MANUFACTURING A CURRENT CONVERTER

(71) Applicant: SCHAEFFLER TECHNOLOGIES AG & CO. KG, Herzogenaurach (DE)

(72) Inventors: Markus Hövermann, Rückersdorf (DE); Michael Haber, Berlin (DE); Peter Krasselt, Heroldsberg (DE); Martin Ehrmann, Nürnberg (DE)

(73) Assignee: Schaeffler Technologies AG & Co. KG, Regensberg (DE)

(21) Appl. No.: 18/998,619

(22) PCT Filed: Jul. 27, 2023
(86) PCT No.: PCT/EP2023/070801

§ 371 Date: Oct. 21, 2025

(30) Foreign Application Priority Data
Jul. 29, 2022 (DE) 10 2022 207 849.7

(51) Int. Cl. H02M 7/00; H05K 7/20

(52) U.S. Cl. CPC H02M 7/003; H05K 7/209

(57) ABSTRACT

The invention relates to a current converter (IV), having:
a plurality of functional base modules (FB), which each form a sub-half-bridge with a positive-voltage-side semiconductor switch (T1) and a negative-voltage-side semiconductor switch (T2) and which each have a plurality of external current terminals (H+, H−, P);
a number of power base modules (LB2, LB3), which each have a plurality of the functional base modules (FB) and an enclosure unit (MM), wherein the enclosure unit (MM) of the respective power base modules (LB2, LB3) mechanically connects together the respective corresponding functional base modules (FB) and encloses them apart from their respective current terminals (H+, H−, P), wherein the functional base modules (FB) of the respective power base modules (LB2, LB3) are electrically insulated from one another within the respective corresponding enclosure unit (MM);
a current converter power module (LM), which has the power base modules (LB2, LB3) and a plurality of current connections (GV, PV), wherein the current connections (GV, PV) electrically connect together the respective corresponding current terminals (H+, H−, P) of the respective functional base modules (FB) of the respective power base modules (LB2, LB3).

The invention also relates to an electric drive device having a said current converter, and to a method for manufacturing a current converter.

### TECHNICAL FIELD

The present invention relates to a current converter, such as an inverter or a DC/DC converter, especially for an electric drive of a motor vehicle, and to an electric drive device comprising a said current converter. Furthermore, the invention relates to a method for manufacturing a current converter.

### PRIOR ART AND OBJECT OF THE INVENTION

Current converters for converting a fed electrical current of one type (direct current, alternating current) into a current of another type (alternating current, direct current) or for changing characteristic parameters, such as the voltage, of a fed current are known and are used, among other things, in electric drive devices of motor vehicles.

As with all technical devices, there is a general requirement for current converters to be optimized in terms of functionality and cost.

The object of the present application is therefore to provide a way of optimizing a current converter in terms of functionality and cost.

### DESCRIPTION OF THE INVENTION

This object is achieved by subject matter of the independent claims. Advantageous embodiments are the subject matter of the dependent claims.

According to a first aspect of the invention, a current converter, in particular an inverter or a DC/DC converter, especially for electrically driving a motor vehicle, is provided.

The current converter has a large number of functional base modules, which each form (only) a sub-half-bridge each with (only) one positive-voltage-side (high-side) semiconductor switch and each (only) one negative-voltage-side (low-side) semiconductor switch and correspondingly each have (only) one positive-voltage-side and (only) one negative-voltage-side semiconductor switch as well as internal current connection(s) between these two semiconductor switches and a plurality of external current connections for establishing external current connections for the semiconductor switches.

The current converter has a number of power base modules, each comprising a plurality (more than one) of the aforementioned functional base modules and each having a mechanical enclosure unit, wherein the enclosure unit of the respective power base modules holds the respective corresponding functional base modules together and mechanically connects them to each other and encloses them apart from their respective external current terminals. The functional base modules of the respective power base modules are electrically (completely) insulated from each other within the respective corresponding enclosure unit.

The current converter has a converter power module which comprises the entire number of power base modules and has a plurality of current connections, wherein the current connections electrically connect together the respective corresponding current terminals of the respective functional base modules of the respective power base modules.

The current converter described above forms a scalable current converter construction concept in three construction stages with a first, a second and a third construction stage:

The first construction stage is formed by the functional base modules, which each form (only) one (switchable) sub-half-bridge with (only) one positive-voltage-side and (only) one negative-voltage-side semiconductor switch and correspondingly (only) one positive-voltage-side and (only) one negative-voltage-side semiconductor switch, as well as internal current connection(s) between these two semiconductor switches and a plurality of external current terminals, e.g., three, namely one positive-voltage-side current terminal, one negative-voltage-side current terminal and one phase-current terminal, for establishing external current connections for the semiconductor switches (external power interfaces for establishing external current connections for the semiconductor switches).

The second construction stage is formed by the power base modules, which each have a plurality of functional base modules of the first construction stage and a mechanical enclosure unit, wherein the enclosure unit of the respective power base modules holds the respective corresponding functional base modules together and mechanically connects them together and encloses them apart from their respective current terminals. The functional base modules of the respective power base modules are electrically (completely) insulated from each other within the respective corresponding enclosure unit.

The third construction stage forms the current converter power module, which has all (more than one) power base modules of the second construction stage and a plurality of current connections, wherein the current connections electrically connect together the respective corresponding current terminals of the respective functional base modules of the respective power base modules.

A functional base module of the first construction stage is a non-divisible base unit (functional base unit) of the power base module and thus of the current converter with a corresponding minimum power/current carrying capacity that cannot be scaled down further. Each functional base module is (only) a complete sub-half-bridge with (only) one positive-voltage-side and (only) one negative-voltage-side semiconductor switch and its own external current terminals for establishing external current connections for the semiconductor switches. The functional base modules can be operated individually or in parallel with other functional base modules. Depending on the requirements, the functional base modules can be identical to one another or structured differently.

A power base module of the second construction stage is a (purely) mechanical and physical combination of a predetermined number of functional base modules, which are enclosed by a common, mechanically stable enclosure unit—apart from their respective external current terminals—and are (purely) mechanically and physically integrated into the respective power base module. The enclosure unit holds the integrated or enclosed functional base modules together mechanically and physically through its own mechanical rigidity and also insulates the functional base modules (internal to the power base module) from each other electrically. The external current terminals, which are not enclosed by the enclosure unit, enable subsequent external electrical connection of the functional base modules in the third construction stage.

A power base module can still only functionally form a sub-half-bridge, which, depending on the power requirement, consists of two, three or more functional base modules or sub-half-bridges that can be connected to each other (in parallel) (but are not yet connected to each other (in parallel) in the second construction stage). The performance or the power/current carrying capacity of the respective power base modules can be scaled by changing the number of functional base modules. In addition, the module size, i.e., the number of integrated functional base modules, can also be selected according to application-specific aspects, such as the type of current converter (e.g., inverter or DC/DC converter), or according to the available current converter installation space or the number of phases (e.g., in the case of an inverter).

The functional base modules in a power base module can be operated individually or in parallel. The number of functional base modules in a power base module determines the required power/current carrying capacity or the desired performance of the power base module or the sub-half-bridge formed from this power base module. A power base module thus forms a power base unit of the current converter.

The compact design of the individual functional base modules and the flexibly definable number of functional base modules in a power base module also allow the power base modules to be integrated into current converter power modules with installation spaces with special geometric requirements. For example, the power base modules can be mounted concentrically on a circular surface, e.g., an end face of a stator of an electrical machine, or radially on the circumference of a cylindrical surface, e.g., a stator of an electrical machine, in an installation-space-saving manner.

The current converter power module of the third construction stage forms the (entire) power-electrical part of the current converter, which—controlled by a suitable driver circuit—converts a fed electrical current of one type (direct current, alternating current) into a current of another type (alternating current, direct current) or changes characteristic parameters such as the voltage of the fed current. As a rule, a current converter power module comprises two, three or more power base modules, which are electrically connected to each other in a switchable double, triple or multiple sub-half-bridge (or double, triple or multiple switching bridge) according to the type and function of the current converter. The electrical connection is made by means of the current connections of the current converter power module, which electrically connect the external current terminals of the respective corresponding functional base modules of the corresponding power base modules.

By selecting the number of functional base modules in a power base module and the number of power base modules in a current converter power module as well as via a corresponding external electrical connection, such as a parallel connection, of the external current terminals of the respective corresponding functional base modules of the corresponding power base modules, the functionality (inverter or DC/DC converter or the number of (electric motor) phases to be supplied with phase currents) can be determined and (additionally) the performance or the power/current carrying capacity of the current converter can be scaled.

In the second construction stage of the current converter, the functional base modules are completely electrically isolated from each other in the respective power base modules or in their respective enclosure units. It is only in the third construction stage of the current converter or in the current converter power module that the functional base modules are electrically connected to each other—in accordance with the functionality and performance of the current converter—via external electrical connections (from the perspective of the functional base modules or the power base modules).

This provides an opportunity to optimize a current converter in terms of functionality and costs.

For example, the functional base modules also each have a plurality of signal connections. The enclosure unit of the respective power base modules also encloses the respective corresponding functional base modules apart from their respective signal connections. The current converter also has one or more driver circuits, each of which is connected to the signal connections of the respective corresponding functional base modules and controls the respective corresponding functional base modules in accordance with the functionality of the current converter.

As the functional base modules are each formed with (only) one positive-voltage-side and (only) one negative-voltage-side semiconductor switch and these semiconductor switches are only electrically connected to the respective corresponding driver circuits via their signal connections in the third expansion stage, the semiconductor switches can each be controlled and monitored individually. This makes it easier to localize defects in the individual semiconductor switches. The separate control of the individual functional base modules also enables the use of static and dynamic measures for balancing the load current on different functional base modules or the semiconductor switches in the various functional base modules.

The enclosure unit of the respective power base modules has, for example, a surface with recesses, wherein the signal connections of the respective functional base modules of the respective corresponding power base modules are exposed through these recesses to produce electrical contacts, in particular in the form of contact surfaces that are exposed through the said recesses.

For example, the functional base modules also each have a cooling surface for cooling the respective functional base modules. The enclosure unit of the respective power base modules also encloses the respective corresponding functional base modules apart from their respective cooling surface. The current converter power module also has a heat sink for cooling the functional base modules, wherein the functional base modules rest on the heat sink via their respective cooling surface and are physically and thermally connected to the heat sink.

The cooling surface of the respective functional base modules of the respective power base modules and the surface of the enclosure unit of the respective corresponding power base modules with the recesses can face away from each other.

The external current terminals of the respective functional base modules of the respective power base modules can extend out of the enclosure unit of the corresponding power base modules in a direction of extension of the surface of the enclosure unit of the respective corresponding power base modules having the recesses. In particular, the external current terminals can extend parallel to the surface mentioned.

For example, the enclosure unit of the respective power base modules encloses the positive-voltage-side and the negative-voltage-side semiconductor switch of the respective functional base modules integrated in the respective corresponding power base modules in an airtight manner.

For example, the enclosure unit comprises a molding compound that is molded or overmolded around the functional base modules of the respective power base modules. The functional base modules are embedded in the respective molding compound and held together mechanically and physically by it. Alternatively or in addition to the molding compound, the enclosure unit also has a carrier frame which (additionally) holds the functional base modules of the respective power base modules together and mechanically and physically connects them together.

For example, the current connections are formed as busbars, which are formed, for example, from a metal sheet, such as a copper sheet, for example by stamping. The busbars can be welded, soldered, sintered or glued, screwed or riveted onto the respective current terminals of the corresponding functional base modules of the respective power base modules. With the busbars, the external power interface of the current converter can be implemented cost-effectively and without functional restrictions.

For example, the functional base modules are identical to one another in terms of their form and functionality, in particular with the same switching properties. In this case, the same number of identical functional base modules are integrated into the respective power base modules during production of the power base modules. Alternatively, the functional base modules can be formed differently in terms of their shape and functionality in groups. In this case, the power base modules from the respective groups of functional base modules of the same form and the same functionality can each have the same number of functional base modules (of the same form and functionality). However, the power base modules are built identically to one another.

This identical design of the functional base modules and power base modules simplifies and enables good current balancing even without additional balancing measures, such as individual semiconductor switch controls using specially adapted driver circuits.

For example, the positive-voltage-side semiconductor switch and the negative-voltage-side semiconductor switch are formed on the basis of silicon carbide or as a silicon carbide transistor switch. In particular, the two semiconductor switches can be formed as SiC-MOSFETs (silicon-carbide metal oxide field-effect transistors) or SiC-IGBTs (silicon-carbide insulated gate bipolar transistors). Alternatively, the two semiconductor switches can also be based on gallium nitride, e.g., as GaN MOSFETs (gallium nitride metal oxide field-effect transistors) or GaN IGBTs (gallium nitride insulated gate bipolar transistors).

According to a second aspect of the invention, an electric drive device is provided. The device has an electrical machine and a current converter described above, which is formed as an inverter. The current converter power module of the current converter is electrically connected to the electrical machine via phase-current connections.

According to a third aspect of the invention, a method for manufacturing a current converter, in particular an inverter or a DC/DC converter, especially for an electric drive of a motor vehicle, is provided.

According to the method, a plurality of functional base modules are provided, which each form (only) a sub-half-bridge each with (only) one positive-voltage-side semiconductor switch and each (only) one negative-voltage-side semiconductor switch and a plurality of current terminals, and correspondingly each have (only) one positive-voltage-side and (only) one negative-voltage-side semiconductor switch as well as internal current connection(s) between these two semiconductor switches and a plurality of external current terminals for establishing external current connections for the semiconductor switches (external power interfaces for establishing external current connections for the semiconductor switches).

A number of power base modules are then formed, each with a plurality of, e.g., two or three, functional base modules and a mechanical enclosure unit. The enclosure unit of the respective power base modules encloses the respective corresponding functional base modules apart from their respective current terminals and connects them to each other mechanically and physically. At the same time, the enclosure unit of the respective power base modules electrically isolates the respective corresponding functional base modules within the respective enclosure unit from one another.

A current converter power module is then formed with the power base modules and a plurality of current connections, wherein the current connections electrically connect together the respective corresponding current terminals of the respective corresponding functional base modules of the corresponding power base modules.

Advantageous configurations of the current converter described above are, insofar as they are transferable to the method mentioned above, also to be regarded as advantageous configurations of the method.

### BRIEF DESCRIPTION OF THE DRAWINGS

Exemplary embodiments of the invention are explained in more detail below with reference to the appended drawings. In the figures:

FIGS. 1A and 1B show a functional base module according to an exemplary embodiment of the invention in a schematic plan view and in a schematic cross-sectional view, respectively;

FIGS. 2A and 2B each show in a schematic plan view a power base module according to an exemplary embodiment of the invention with functional base modules from FIGS. 1A and 1B, respectively;

FIG. 3 shows a schematic cross-sectional view of the power base module of FIGS. 2A and 2B; and

FIG. 4 shows a schematic representation of an electric drive with an inverter with power base modules from FIG. 2B.

### DETAILED DESCRIPTION OF THE DRAWINGS

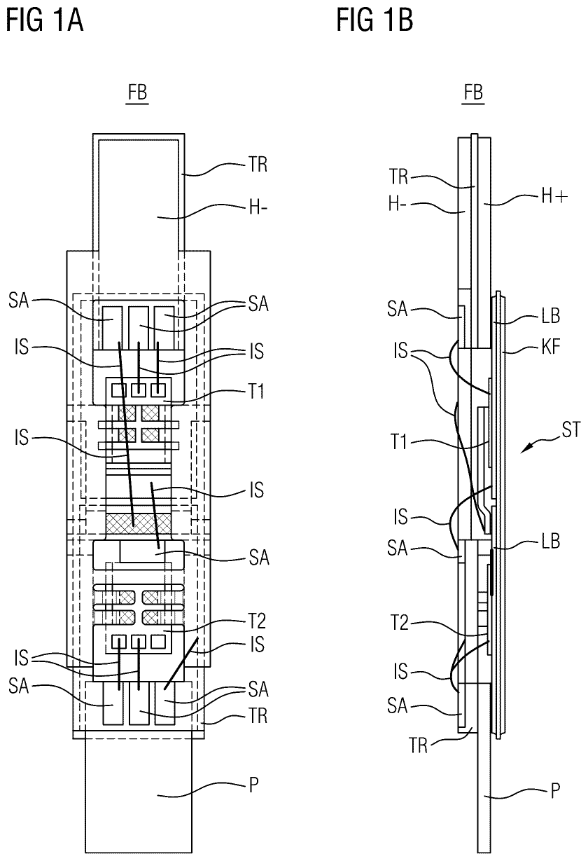

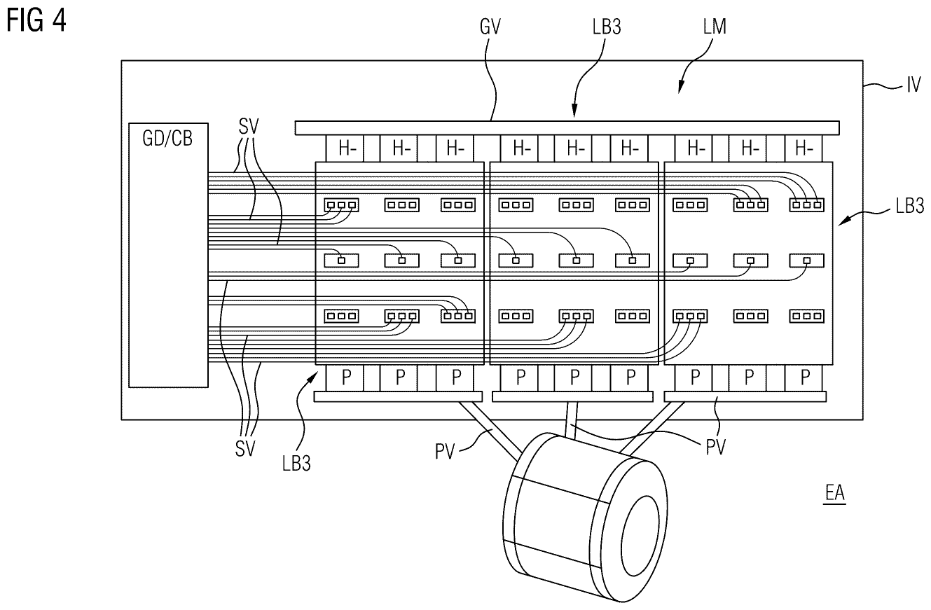

FIGS. 1A and 1B show a schematic plan view (FIG. 1A) and a schematic cross-sectional view (FIG. 1B) of a functional base module FB of an inverter IV according to an exemplary embodiment of the invention. The inverter IV is part of an electric drive device EA of an electric vehicle for operating an electrical machine EM (see FIG. 4).

The functional base module FB forms only a sub-half-bridge of the power module LM of the inverter IV and thus—as the first construction stage of the power module LM of the inverter IV—a non-divisible functional base unit of the power module LM of the inverter IV. Accordingly, the functional base module FB has a single positive-voltage-side semiconductor switch T1 and a single negative-voltage-side semiconductor switch T2. Furthermore, the functional base module FB has a single positive-voltage-side current terminal, a single negative-voltage-side current terminal and a single phase-current terminal, via which the functional base module FB establishes external current connections between the module-internal semiconductor switches T1, T2 on the one hand and module-external direct current supply (“DC link”) and a phase line of the electrical machine EM on the other.

The two semiconductor switches T1, T2 are formed as silicon carbide transistors. The positive-voltage-side current terminal, the negative-voltage-side current terminal and the phase-current terminal are each formed as a positive-voltage-side busbar H+, a negative-voltage-side busbar H− and a phase busbar P respectively, which are stamped and formed from a copper sheet.

The functional base module FB has an AMB substrate (AMB: “Active Metal Brazing”) as a circuit carrier ST of the sub-half-bridge, which has a layered/plate-shaped electrical insulator made of aluminum oxide (Al2O3), aluminum nitride (AlN), silicon nitride (Si3N4) or a comparable ceramic substrate material, and a copper layer on each of the two flat extended upper sides of the insulator.

A first copper layer on a first upper side of the insulator forms conductor tracks for establishing current connections between the semiconductor switches T1, T2 on the one hand and the positive-voltage-side busbar H+ or the phase busbar P on the other. Accordingly, the first copper layer is structured on the first upper side according to the function of the functional base module FB (as a sub-half-bridge). The two semiconductor switches T1, T2 are surface-mounted on the respective conductor tracks LB.

A second copper layer on a second upper side of the insulator facing away from the first upper side forms a cooling surface KF of the functional base module FB, via which the waste heat from the functional base module FB or from the two semiconductor switches T1, T2 is dissipated during operation of the inverter IV. Accordingly, the second copper layer (in particular in one piece) extends over almost the entire surface of the second upper side.

The positive-voltage-side and negative-voltage-side busbars H+, H− and the phase busbar P are electrically connected to the respective semiconductor switches T1, T2 according to the function of the functional base module FB (as a sub-half-bridge) directly or via the conductor tracks on the circuit carrier ST, or possibly via other connecting elements such as bonding wires, bonding ribbons or metal stamped connecting parts.

The functional base module FB also has one or more support frames TR made of an electrically insulating material, e.g., in the form of molding compounds, which support the busbars H+, H−, P, physically connect them to each other and to the circuit carrier ST and at the same time electrically insulate them from each other. On the upper sides facing away from the circuit carrier ST and thus its cooling surface KF, the carrier frames TR have signal connections SA made of copper plates, which are embedded in the carrier frame TR except for their respective exposed contact surfaces. The functional base module FB also has internal signal connections IS in the form of bond connections, which electrically connect the respective signal connections SA to the corresponding control or signal connections of the respective corresponding semiconductor switches T1, T2 in accordance with the function of the functional base module FB (as a sub-half-bridge).

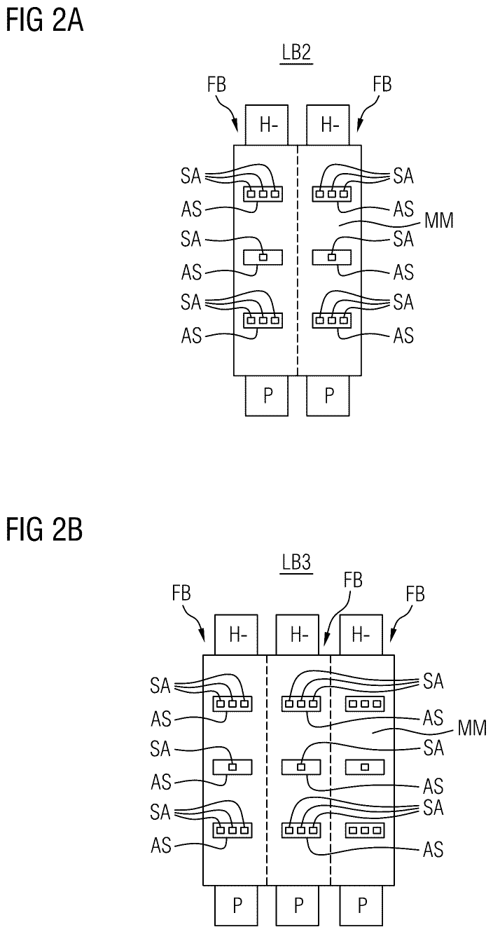

FIGS. 2A, 2B each show a schematic plan view of a power base module LB2 (FIG. 2A), LB3 (FIG. 2B) according to exemplary embodiments of the invention, each with two or three functional base modules FB from FIGS. 1A and 1B.

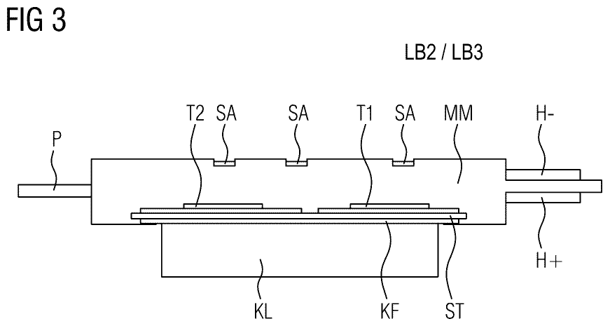

The power base module LB2 in FIG. 2A has two functional base modules FB which are identical to one another and which—apart from the respective exposed end portions of the respective external busbars H+, H−, P, respective signal connections SA and respective cooling surface KF (see FIG. 3)—are completely enclosed in a common, mechanically stable enclosure unit MM in the form of a molding compound and are thus (purely) mechanically and physically integrated into the respective power base module. The molding compound MM has recesses AS, which expose the signal connections SA and the cooling surface KF for external electrical or thermal contacts. The recesses AS for the signal connections SA are formed on a surface of the molding compound MM facing away from the cooling surface KF. The busbars H+, H−, P extend out of the molding compound MM in a direction of extension of the above-mentioned surface of the molding compound MM, in particular parallel to the plane of said surface.

Similarly, the power base module LB3 in FIG. 2B has three functional base modules FB which are identical to one another and which—apart from the respective exposed end portions of the respective external busbars H+, H−, P, respective signal connections SA and respective cooling surface KF (see FIG. 3)—are completely enclosed in a common, mechanically stable enclosure unit MM in the form of a molding compound and are thus (purely) mechanically and physically integrated into the respective power base module. The molding compound MM has recesses AS, which expose the signal connections SA and the cooling surface KF for external electrical or thermal contacts. The recesses AS for the signal connections SA are formed on a surface of the molding compound MM facing away from the cooling surface KF. The recesses AS for the signal connections SA are formed on a surface of the molding compound MM facing away from the cooling surface KF. The busbars H+, H−, P extend out of the molding compound MM in a direction of extension of the above-mentioned surface of the molding compound MM, or parallel to the plane of said surface.

The power base modules LB2, LB3, as the second construction stage of the power module LM of the inverter IV, each form a (purely) mechanical and physical composite of a predetermined number—in these embodiments two or three—of functional base modules FB, which are each completely enclosed by a common, mechanically stable molding compound MM—apart from their respective external power and signal connections H+, H−, P and SA, as well as their respective cooling surface KF—and are integrated purely mechanically and physically into the respective power base modules LB2, LB3. The molding compound MM holds the integrated or enclosed functional base modules FB together mechanically and physically through its own mechanical rigidity and also insulates the functional base modules FB (internal to the power base module) from each other electrically. The external power and signal connections H+, H−, P and SA, which are not enclosed by the molding compound MM, enable a later, external electrical connection of the functional base modules FB in the third construction stage to be described below.

The two power base modules LB2, LB3 each continue to form only one sub-half-bridge in functional terms, wherein the functional base modules FB in the respective power base modules LB2, LB3 can be connected in parallel to each other. The two power base modules LB2 and LB3 differ only in terms of performance or power/current carrying capacity.

Depending on the power requirement, power base modules can also be formed, which consist of four or more functional base modules or sub-half-bridges. The performance or the power/current carrying capacity of the power base modules can be scaled by changing the number of functional base modules. In addition, the module size, i.e., the number of integrated functional base modules, can also be selected according to application-specific aspects, such as the type of current converter (e.g., inverter or a DC/DC converter), or according to the current converter installation space or the number of phases (e.g., in the case of an inverter).

The functional base modules in a power base module can be operated individually or in parallel, depending on their subsequent interconnection in the third configuration stage to be described below. The number of functional base modules in a power base module and their subsequent interconnection determine the power/current carrying capacity or the performance of the power base module. A power base module thus forms a power base unit.

FIG. 3 shows a schematic cross-sectional view of the power base module LB2 from FIG. 2A or the power base module LB3 from FIG. 2B—since the two power base modules LB2, LB3 differ from each other only in the number of integrated functional base modules FB, the two power base modules LB2, LB3 have the same cross-sectional view.

The power base modules LB2, LB3 each have a molding compound MM as the common, mechanically stable enclosure unit, which completely surrounds the respective functional base modules FB except for their respective signal connections SA, their respective cooling surface KF and the exposed end sections of the respective external busbars H+, H−, P and thus protects the functional base modules FB from environmental influences. In addition, the molding compound MM also acts as a support for the functional base modules FB and the power base module LB2, LB3 embedded in it due to its own mechanical rigidity and gives it mechanical stability.

Optionally, the power base modules LB2, LB3 each have a cooler KL of known type, on which the functional base modules FB of the respective power base modules LB2, LB3 rest via their respective, flatly extended cooling surface KF and to which they are physically and thermally connected.

In this second construction stage of the power module LM of the inverter IV, the functional base modules FB of the respective power base modules LB2, LB3 are only connected purely mechanically by the respective molding compound MM. In particular, the functional base modules FB of the respective power base modules LB2, LB3 are completely electrically insulated from each other by the respective molding compound MM. The functional base modules FB of the respective power base modules LB2, LB3 are not electrically connected together—in accordance with the functionality and performance of the inverter IV—until the third construction stage of the power module LM of the inverter IV, to be described below, via external electrical connections (from the perspective of the functional base modules FB or the power base modules LB2, LB3).

Thus, the power base modules LB2, LB3 of the second construction stage each form a purely mechanical and physical composite of a predetermined number (two or three) of the functional base modules FB, which are mechanically and physically integrated into the respective power base modules LB2, LB3 by the common, mechanically stable molding compound MM. The molding compound MM holds the integrated or enclosed functional base modules FB together mechanically and physically through its own mechanical rigidity and also insulates the functional base modules FB (internal to the power base module) from each other electrically. The external power/signal connections H+, H−, P and SA, which are not enclosed by the molding compound MM, enable a later external electrical connection of the functional base modules FB in the third construction stage.

FIG. 4 shows a schematic representation of an electric drive EA with an electrical machine EM and an inverter IV for operating the electrical machine EM. The inverter IV has a power module LM, which in turn has three power base modules LB3 from FIG. 2B, a driver circuit GD and a control circuit CB for operating the power module LM.

The power module LM forms the third stage of the power module LM of the inverter IV or the (entire) power-electrical part of the inverter IV. The three power base modules LB3 each form one of three sub-half-bridges with a corresponding power/current carrying capacity of the inverter IV.

The drive EA also has a DC connection GV, via which the respective positive-voltage-side or the respective negative-voltage-side busbars H+, H− are electrically connected to the functional base modules FB of the respective power base modules LB3 on an intermediate circuit of the drive EA, which is not shown in the figure.

The drive EA also has three phase-current connections PV, via which the three power base modules LB3 are each electrically connected to one of the three windings of the electrical machine EM.

The drive EA also has a plurality of signal connections SV (for a better overview, only parts of these are shown schematically in the figure), via which the driver circuit GD or the control circuit CB are electrically connected to the respective functional base modules FB or to their respective signal connections.

In this third construction stage of the power module LM of the inverter IV, the functional base modules FB are electrically interconnected externally but also partly internally.

The inverter IV or its power module LM is therefore available with a freely scalable design concept in three construction stages with the first, second and third construction stages, depending on the performance requirements:

The first construction stage is formed by the functional base modules FB, which, as a non-divisible functional base unit of the power base module LB3 or of the power module LM each have (only) one (switchable) sub-half-bridge with (only) one positive-voltage-side and (only) one negative-voltage-side semiconductor switch T1, T2 and external current terminals H+, H− and P for establishing external current connections for the semiconductor switches T1, T2—i.e., external power interfaces for establishing external current connections for the semiconductor switches.

The second construction stage is formed by the power base modules LB3, which each have a plurality of functional base modules FB of the first construction stage and a molding compound MM as a mechanical enclosure unit, wherein the molding compound MM of the respective power base modules LB3 holds the respective corresponding functional base modules FB together and mechanically connects them together and (completely) encloses them apart from their respective power/signal connections H+, H− and P and also SA. The functional base modules FB of the respective power base modules LB3 are electrically insulated from each other within the respective corresponding molding compound MM. If required, thermal interfaces of the functional base modules FB or the power base modules LB3, namely the cooling surface KF and/or the cooler KL can also be at least partially molded by the molding compound MM.

The third construction stage forms the power module LM as the (entire) power-electrical part of the inverter IV, which has all the power base modules LB3 of the second construction stage and all the necessary current connections GV, PV and signal connections SV, wherein the current and signal connections GV, PV, SV electrically connect together the respective corresponding current/signal connections H+, H− and P and SA of the functional base modules LB3 of the respective power base modules LB3.

By selecting the number of functional base modules FB in the power base module LB3 and the number of power base modules LB3 in the power module LM, the functionality and performance or the power/current carrying capacity of the inverter IV can be scaled.

The compact design of the individual functional base modules FB and the flexibly definable number of functional base modules FB in a power base module LB3 also enable flexible integration of the power base modules LB3 in the power module LM with special geometric requirements. For example, the power base modules LB3 can be mounted concentrically on a circular surface, e.g., an end face of the stator of the electrical machine EM, or radially on the circumference of a cylindrical surface of the stator of an electrical machine EM in an installation-space-saving manner.

The external electrical connection of the functional base modules FB only in the third construction stage increases flexibility in the design of the inverter. This also facilitates symmetrical current distribution in the design of the power module LM and subsequent design adjustments. This in turn enables a high switching speed for the semiconductor switches T1, T2 used and thus the use of fast-switching, low-loss SiC semiconductor switches as well as very low parasitic inductances in the load and control circuit of the semiconductor switches T1, T2.

This allows the inverter IV to be manufactured in a functionally and cost-optimized manner.

1. A current converter (IV), having:
a plurality of functional base modules (FB), which each form a sub-half-bridge with a positive-voltage-side semiconductor switch (T1) and a negative-voltage-side semiconductor switch (T2) and which each have a plurality of external current terminals (H+, H−, P);
a number of power base modules (LB2, LB3), which each have a plurality of the functional base modules (FB) and an enclosure unit (MM), wherein the enclosure unit (MM) of the respective power base modules (LB2, LB3) mechanically connects together the respective corresponding functional base modules (FB) and encloses them apart from their respective current terminals (H+, H−, P), wherein the functional base modules (FB) of the respective power base modules (LB2, LB3) are electrically insulated from one another within the respective corresponding enclosure unit (MM);
a current converter power module (LM), which has the power base modules (LB2, LB3) and a plurality of current connections (GV, PV), wherein the current connections (GV, PV) electrically connect together the respective corresponding current terminals (H+, H−, P) of the respective functional base modules (FB) of the respective power base modules (LB2, LB3).

2. The current converter (IV) as claimed in claim 1,
wherein the functional base modules (FB) furthermore each have a plurality of signal connections (SA);
wherein the enclosure unit (MM) of the respective power base modules (LB2, LB3) also encloses the respective corresponding functional base modules (FB) apart from their respective signal connections (SA);
wherein the current converter (IV) also has driver circuits (GD), which are each connected to the signal connections (SA) of the respective corresponding functional base modules (FB).

3. The current converter (IV) as claimed in claim 2, wherein the enclosure unit (MM) of the respective power base modules (LB2, LB3) has a surface with recesses (AS), whereby the signal connections (SA) of the respective functional base modules (FB) of the respective corresponding power base modules (LB2, LB3) are exposed for electrical contacting.

4. The current converter (IV) as claimed in one of the preceding claims,
wherein the functional base modules (FB) further each have a cooling surface (KF) for cooling the respective functional base modules (FB);
wherein the enclosure unit (MM) of the respective power base modules (LB2, LB3) also encloses the respective corresponding functional base modules (FB) apart from their respective cooling surface (KF);
wherein the current converter power module (LM) also has a heat sink (KL) for cooling the functional base modules (FB), wherein the functional base modules (FB) rest on the heat sink (KL) via their respective cooling surface (KF) and are thermally connected to the heat sink (KL).

5. The current converter (IV) as claimed in claims 3 and 4, wherein the cooling surface (KF) of the respective functional base modules (FB) of the respective power base modules (LB2, LB3) and the surface of the enclosure unit (MM) of the respective corresponding power base modules (LB2, LB3) with the recesses (AS) face away from each other.

6. The current converter (IV) as claimed in claim 3 or 5, wherein the external current terminals (H+, H−, P) of the respective functional base modules (FB) of the respective power base modules (LB2, LB3) extend out of the enclosure unit (MM) of the corresponding power base modules (LB2, LB3) in a direction of extension of the surface of the enclosure unit (MM) of the respective corresponding power base modules (LB2, LB3) having the recesses (AS).

7. The current converter (IV) as claimed in one of the preceding claims, wherein the enclosure unit (MM) of the respective power base modules (LB2, LB3) encloses the positive-voltage-side (T1) and the negative-voltage-side (T2) semiconductor switch of the respective corresponding functional base modules (FB) in an airtight manner.

8. The current converter (IV) as claimed in one of the preceding claims, wherein the enclosure unit (MM) comprises a molding compound which is molded around the functional base modules (FB) of the respective power base modules (LB2, LB3).

9. The current converter (IV) as claimed in one of the preceding claims, wherein the enclosure unit (MM) has a carrier frame which holds the functional base modules (FB) of the respective power base modules (LB2, LB3) and mechanically connects them together.

10. The current converter (IV) as claimed in one of the preceding claims, wherein the current connections are formed as busbars.

11. The current converter (IV) as claimed in one of the preceding claims, wherein the functional base modules (FB) are constructed identically to one another and/or the power base modules (LB2, LB3) each have the same number of identical functional base modules (FB).

12. The current converter (IV) as claimed in one of the preceding claims, wherein the positive-voltage-side semiconductor switch (T1) and the negative-voltage-side semiconductor switch (T2) are formed on the basis of silicon carbide.

13. An electric drive device (EA), comprising:
an electrical machine (EM) and
a current converter (IV) as claimed in one of the preceding claims, which is formed as an inverter;
wherein the current converter power module (LM) of the current converter (SR) is electrically connected to the electrical machine (EM) via phase-current connections (PV).

14. A method for manufacturing a current converter (IV), comprising the following steps:
providing a plurality of functional base modules (FB), which each form a sub-half-bridge with a positive-voltage-side semiconductor switch (T1) and a negative-voltage-side semiconductor switch (T2) as well as a plurality of current terminals (H+, H−, P);
forming a number of power base modules (LB2, LB3), which each have a plurality of functional base modules (FB) and an enclosure unit (MM), wherein the enclosure unit (MM) of the respective power base modules (LB2, LB3) encloses and mechanically connects the respective corresponding functional base modules (FB) apart from their respective current terminals (H+, H−, P) and mechanically connects them together, wherein the functional base modules (FB) of the respective power base modules (LB2, LB3) are electrically insulated from one another within the respective corresponding enclosure unit (MM);
forming a current converter power module (LM) with the power base modules (LB2, LB3) and a plurality of current connections (GV, PV), wherein the current connections (GV, PV) electrically connect together the respective corresponding current terminals H+, H−, P) of the respective functional base modules (FB) of the respective power base modules (LB2, LB3).
